(19) United States
(12) Patent Application Publication
(10) Pub. No.: US 2025/0338605 A1
(43) Pub. Date: Oct. 30, 2025

(54) INTEGRATED CIRCUIT STRUCTURE

(71) Applicant: Winbond Electronics Corp., Taichung City (TW)

(72) Inventors: Yi-Chun Chen, Tainan City (TW); Noriaki Ikeda, Kaohsiung City (TW); Hsiang-Po Liu, Taichung City (TW); Kai-Hsiang Chang, Taichung City (TW)

(73) Assignee: Winbond Electronics Corp., Taichung City (TW)

(21) Appl. No.: 18/963,558

(22) Filed: Nov. 28, 2024

(30) Foreign Application Priority Data
Apr. 26, 2024 (TW) 113115724

(51) Int. Cl. H01L 27/088; H01L 27/02

(52) U.S. Cl. CPC H10D 84/83; H10D 89/10

(57) ABSTRACT

An integrated circuit structure includes a first active area, a second active area, a first connection part, a second connection part, and a well area. The first active area has a first side. The second active area has a second side opposite to the first side of the first active area. The first connection part is connected between a first part of the first side of the first active area and a first part of the second side of the second active area. The second connection part is connected between a second part of the first side of the first active area and a second part of the second side of the second active area. The first side, the second side, the first connection part, and the second connection part surround the well area.

### CROSS-REFERENCE TO RELATED APPLICATION

This application claims the priority benefit of Taiwan application serial no. 113115724, filed on Apr. 26, 2024. The entirety of the above-mentioned patent application is hereby incorporated by reference herein and made a part of this specification.

### BACKGROUND

### Technical Field

The disclosure relates to an integrated circuit structure, and particularly relates to an integrated circuit structure that can improve the stability of its electrical characteristics.

### Description of Related Art

In order to perform temperature compensation in a memory device, the layout structure of the sense amplifying circuit requires a well pick up area between the active areas as a medium for transmitting the well area voltage. In the conventional art, the well pick up area is provided between dielectric structures. The active area will be cut off by the well pick up area and the corresponding dielectric structure, resulting in a discontinuous area in the layout. This discontinuous layout phenomenon will cause the transistors arranged on two sides to have non-uniform electrical characteristics due to the discontinuous load corresponding to the active area. Under such circumstances, the electrical characteristics (such as on-state voltage) between the transistors will vary to a certain extent, reducing the performance of the sense amplifying circuit.

### SUMMARY

The disclosure provides an integrated circuit structure that can improve the potential mismatch state in the layout of the integrated circuit and improve the stability of its electrical characteristics.

An integrated circuit structure of the disclosure includes a first active area, a second active area, a first connection part, a second connection part, and a well area. The first active area has a first side. The second active area has a second side opposite to the first side of the first active area. The first connection part is connected between a first part of the first side of the first active area and a first part of the second side of the second active area. The second connection part is connected between a second part of the first side of the first active area and a second part of the second side of the second active area. The first side, the second side, the first connection part, and the second connection part surround the well area.

Based on the above, in the integrated circuit structure of the disclosure, the first active area and the second active area around the well area can be connected to each other through the first connection part and the second connection part. Under such conditions, the well area may be surrounded by the first active area, the second active area, the first connection part, and the second connection part. Each transistor disposed around the active area may be adjacent to each of the first active area, the second active area, the first connection part, and the second connection part. Under such conditions, each transistor may have substantially a same load corresponding to the first active area, the second active area, the first connection part, and the second connection part, which can effectively improve the uniformity of the electrical characteristics of the transistor.

### BRIEF DESCRIPTION OF THE DRAWINGS

FIG. 1 is a top view of an integrated circuit structure according to an embodiment of the disclosure.

FIG. 2 is a partially enlarged schematic view of an integrated circuit structure 100.

FIG. 3 is a schematic view of a cross-sectional structure of an integrated circuit according to an embodiment of the disclosure.

FIG. 4 is a schematic view of a cross-sectional structure of a well area of an integrated circuit according to an embodiment of the disclosure.

FIG. 5 is a top view of a layout structure of an integrated circuit according to an embodiment of the disclosure.

### DESCRIPTION OF THE EMBODIMENTS

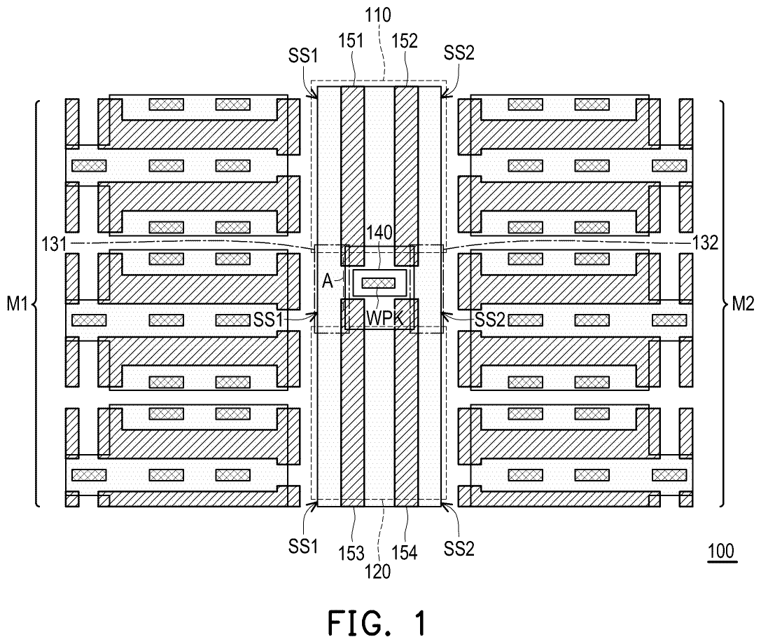

Referring to FIG. 1, which is a top view of an integrated circuit structure according to an embodiment of the disclosure. An integrated circuit structure 100 includes a first active area 110, a second active area 120, a first connection part 131, a second connection part 132, and a well area 140. The first connection part 131 and the second connection part 132 are connected between the first active area 110 and the second active area 120. Moreover, the first active area 110, the second active area 120, the first connection part 131, and the second connection part 132 may surround an area. The well area 140 may be disposed in the area surrounded by the first active area 110, the second active area 120, the first connection part 131, and the second connection part 132.

In the embodiment, a conductive structure WPK may be disposed on the well area 140, and the conductive structure WPK is configured to form a well pick up area of the well area 140.

In addition, the first active area 110, the second active area 120, the first connection part 131, and the second connection part 132 may be of a same silicon material. The first active area 110, the second active area 120, the first connection part 131, and the second connection part 132 may be an integrally formed structure. The first active area 110, the second active area 120, and the first connection part 131 may have a mutually aligned side SS1, and the first active area 110, the second active area 120, and the second connection part 132 may have a mutually aligned side SS2. In the embodiment, a plurality of transistors M1 may be disposed at the outside of the side SS1, and a plurality of transistors M2 may be disposed at the outside of the side SS2. The side SS1 and the side SS2 are two opposite sides.

Incidentally, in the integrated circuit structure 100, the first active area 110 also has polycrystalline silicon structures 151 and 152 disposed thereon. The polycrystalline silicon structures 151 and 152 may have a same extending direction as the first active area 110. The second active area 120 may have polycrystalline silicon structures 153 and 154 disposed thereon. The polycrystalline silicon structures 153 and 154 may have a same extending direction as the second active area 120.

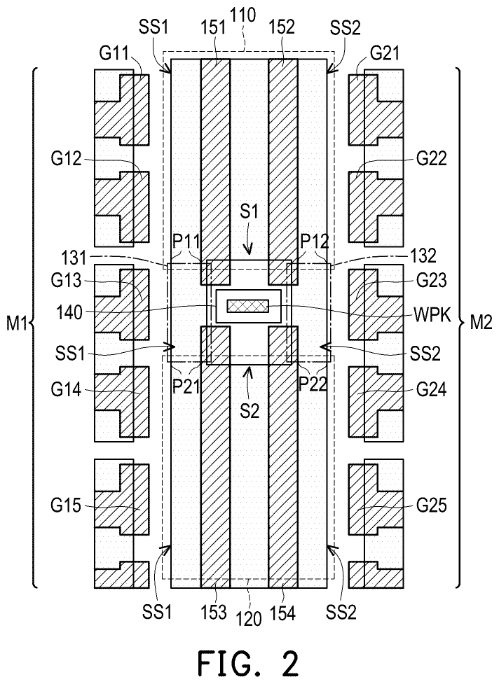

For details, please refer to the partially enlarged schematic view of the integrated circuit structure 100 shown in FIG. 2. The first active area 110 has a first side S1, and the second active area 120 has a second side S2. The first side S1 of the first active area 110 is opposite to the second side S2 of the second active area 120. The first side S1 of the first active area 110 has a first part P11 and a second part P12. The first part P11 and the second part P12 are isolated from each other and are not directly adjacent to each other. The second side S2 of the second active area 120 has a first part P21 and a second part P22. The first part P21 and the second part P22 are isolated from each other and are not directly adjacent to each other. In the configuration position, the first part P11 of the first side S1 of the first active area 110 may correspond to the first part P21 of the second side S2 of the second active area 120, the second part P12 of the first side S1 of the first active area 110 may correspond to the second part P22 of the second side S2 of the second active area 120. The first connection part 131 may be disposed between the first part P11 of the first side S1 of the first active area 110 and the first part P21 of the second side S2 of the second active area 120. The second connection part 132 may be disposed between the second part P12 of the first side S1 of the first active area 110 and the second part P22 of the second side S2 of the second active area 120. In the embodiment, the first connection part 131 and the second connection part 132 may be parallel to each other.

In FIG. 2, a plurality of gates G11 to G15 of the plurality of transistors M1 are sequentially disposed at the outside of the side SS1 where the first active area 110, the second active area 120, and the first connection part 131 are aligned with each other. Each gate G11 to G15 can be spaced at a same distance from the side SS1. In this way, the load of each transistor M1 corresponding to the same side SS1 of the first active area 110, the first connection part 131, and the second active area 120 can be the same. Please note here that based on possible deviations caused by the manufacturing process, the load of each transistor M1 corresponding to the same side SS1 of the first active area 110, the first connection part 131, and the second active area 120 may have slight errors between each other. Therefore, the load of each transistor M1 corresponding to the same side SS1 of the first active area 110, the first connection part 131, and the second active area 120 is substantially the same.

Similarly, the plurality of gates G21 to G25 of the plurality of transistors M2 are sequentially disposed at the outside of the side SS2 where the first active area 110, the second active area 120, and the second connection part 132 are aligned with each other. Each gate G21 to G25 can be spaced at a same distance from the side SS2. In this way, the load of each transistor M2 corresponding to the same side SS2 of the first active area 110, the second connection part 132, and the second active area 120 is substantially the same.

The integrated circuit structure 100 of the embodiment of the disclosure can be disposed in a sense amplifying circuit of a memory device. Of course, the integrated circuit structure 100 can also be disposed in other circuits, which should however not be construed as a limitation in the disclosure.

Based on the above, in the integrated circuit structure 100 of the embodiment of the disclosure, by disposing the first connection part 131 and the second connection part 132 of the same material between the first active area 110 and the second active area 120, the uniformity of the layout of the plurality of transistors M1 and M2 can be effectively improved. Under such circumstances, the uniformity of the electrical characteristics of the transistors M1 and M2 can be effectively improved, thereby improving the working performance of the integrated circuit.

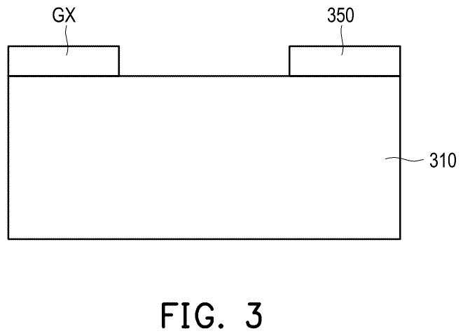

Referring to FIG. 3 below, FIG. 3 is a schematic view of a cross-sectional structure of an integrated circuit according to the embodiment of FIG. 1 of the disclosure. The cross-sectional structure of FIG. 3 is a cross-sectional structure view according to a line segment A in the embodiment of FIG. 1. A silicon structure 310 can be formed by integrally forming the first active area, the second active area, and the first connection part (or the second connection part). A polycrystalline silicon structure Gx may be formed on one side of the structure 310. A polycrystalline silicon structure 350 may be formed on the other side of the structure 310.

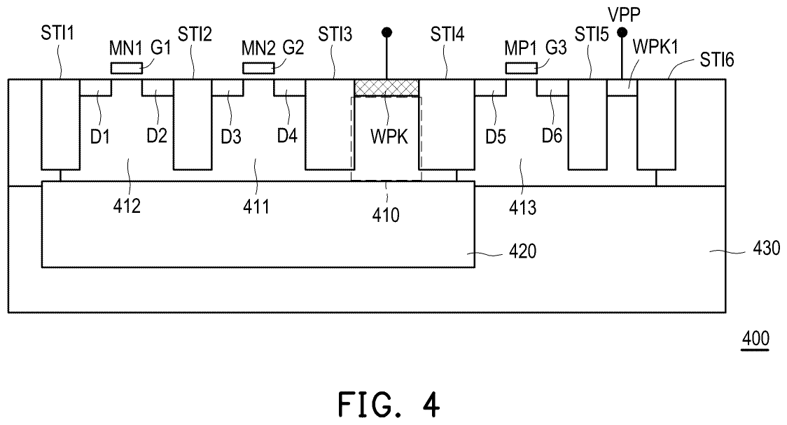

Referring to FIG. 4 below, FIG. 4 is a schematic view of a cross-sectional structure of a well area of an integrated circuit according to an embodiment of the disclosure. An integrated circuit 400 has well areas 410, 411, 412, and 413, a deep well area 420, a substrate 430, and a plurality of dielectric structures STI1 to STI6. The deep well area 420 is formed in the substrate 430, and the well areas 410, 411, and 412 are formed on the deep well area 420. The well area 413 is formed on the substrate 430. The dielectric structures STI1 to STI3 are configured to sequentially separate the well areas 412, 411, and 410. The dielectric structure STI4 is formed between the well areas 410 and 413.

The well area 412 has heavily doped areas D1 and D2, and a gate G1 is covered on the well area 412 between the heavily doped areas D1 and D2. The well area 412, the heavily doped areas D1 and D2, and the gate G1 form a transistor MN1. The well area 411 has heavily doped areas D3 and D4, and a gate G2 is covered on the well area 411 between the heavily doped areas D3 and D4. The well area 411, the heavily doped areas D3 and D4, and the gate G2 form a transistor MN2. The well area 413 has heavily doped areas D5 and D6, and a gate G3 is covered on the well area 413 between the heavily doped areas D5 and D6. The well area 413, the heavily doped areas D5 and D6, and the gate G3 form a transistor MP1.

Additionally, the conductive structure WPK is covered on the well area 410 and forms a well pick up area. The conductive structure WPK is configured to transmit a voltage VBB on the well area 410.

Incidentally, in the embodiment, the well areas 410, 411, and 412 may be directly connected to each other at the bottom positions. The well areas 410, 411, and 412 may be P-type well areas, and the transistors MN1 and MN2 may be N-type transistors. The well area 413 may be an N-type well area, and the transistor MP1 may be a P-type transistor. Correspondingly, the deep well area 420 may be an N-type deep well area, and the substrate 430 may be a P-type substrate.

In addition, the dielectric structures STI5 and STI6 are sequentially formed on a side of the well area 413 adjacent to the heavily doped area D6. The dielectric structures STI5 and STI6 are configured to isolate an area in the well area 413, and a conductive structure WPK1 is disposed in this area to serve as a well pick up area of the well area 413. The conductive structure WPK1 can be configured to transmit a voltage VPP.

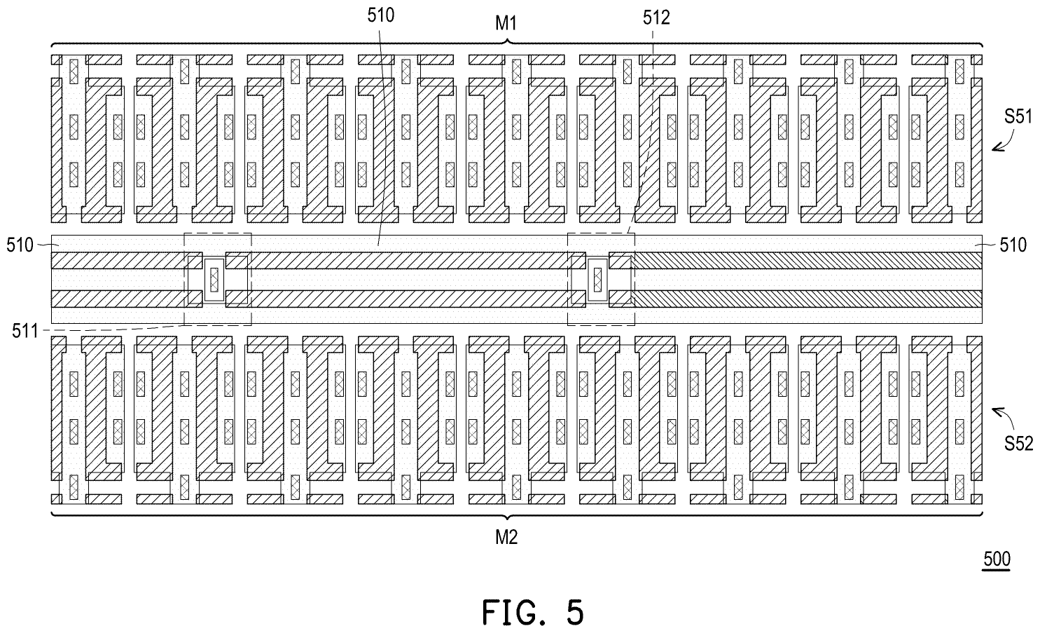

Referring to FIG. 5 below, FIG. 5 is a top view of a layout structure of an integrated circuit according to an embodiment of the disclosure. In an integrated circuit 500, a plurality of transistors M1 may be disposed on a first side S51 of the integrated circuit 500, and a plurality of transistors M2 may be disposed on a second side S52 of the integrated circuit 500. Between the layout area of the transistors M1 and the transistors M2, a plurality of integrated circuit structures 511 and 512 may be periodically (or aperiodically) disposed between a plurality of sequential active areas 510. Each of the integrated circuit structures 511 and 512 can be similar to the integrated circuit structure 100 shown in FIGS. 1 and 2 of the disclosure, and the relevant details are not repeated here.

In the embodiment, the number of the integrated circuit structures 511 and 512 can be set according to the actual layout of the integrated circuit 500, which should however not be construed as a limitation in the disclosure.

According to the illustration in FIG. 5, it can be known that by arranging the plurality of integrated circuit structures 511 and 512, the plurality of transistors M1 and the plurality of transistors M2 in the integrated circuit 500 can have substantially a same load in the direction of the active area, which can effectively improve the uniformity of the layout structure and improve the stability of electrical characteristics.

In summary, the integrated circuit structure of the disclosure connects the first active area and the second active area to each other through the first connection part and the second connection part. Furthermore, the first connection part, the second connection part, the first active area, and the second active area form a surrounding area to surround the well area having the well pick up area. Under such an arrangement, the load of the transistors corresponding to the direction of the active area on two sides of the integrated circuit structure can be substantially the same. Moreover, the layout uniformity of the transistors on two sides of the integrated circuit structure can be effectively improved, thereby improving the uniformity of the electrical characteristics of the transistors and ensuring the working efficiency of the circuit.

What is claimed is:

1. An integrated circuit structure, comprising:
a first active area, having a first side;
a second active area, having a second side opposite to the first side of the first active area;
a first connection part, connected between a first part of the first side of the first active area and a first part of the second side of the second active area;
a second connection part, connected between a second part of the first side of the first active area and a second part of the second side of the second active area; and
a well area,
wherein the first side, the second side, the first connection part, and the second connection part surround the well area.

2. The integrated circuit structure according to claim 1 further comprising:
a plurality of first transistors, disposed at an outside of a same side of the first active area, the first connection part, and the second active area; and
a plurality of second transistors, disposed at an outside of a same side of the first active area, the second connection part, and the second active area.

3. The integrated circuit structure according to claim 2, wherein a load of the first transistors corresponding to the same side of the first active area, the first connection part, and the second active area is substantially the same.

4. The integrated circuit structure according to claim 2, wherein a load of the second transistors corresponding to the same side of the first active area, the second connection part, and the second active area is substantially the same.

5. The integrated circuit structure according to claim 1 further comprising:
a conductive structure, disposed on the well area to form a well pick up area.

6. The integrated circuit structure according to claim 1, wherein the first active area, the second active area, the first connection part, and the second connection part are of a same silicon material.

7. The integrated circuit structure according to claim 6, wherein the first active area, the second active area, the first connection part, and the second connection part are an integrally formed structure.

8. The integrated circuit structure according to claim 1, further comprising:
at least one first polycrystalline silicon structure, disposed on the first active area; and
at least one second polycrystalline silicon structure, disposed on the second active area.

9. The integrated circuit structure according to claim 1, further comprising:
a dielectric structure, disposed between the first active area, the second active area, the first connection part, the second connection part, and the well area.

10. The integrated circuit structure according to claim 1, wherein the first part of the first side of the first active area and the second part of the first side of the first active area are separated from each other, and the first part of the second side of the second active area and the second part of the second side of the second active area are separated from each other.

11. The integrated circuit structure according to claim 1, wherein the first connection part and the second connection part are parallel to each other.

12. The integrated circuit structure according to claim 1, wherein the well area is disposed on a deep well area.

13. The integrated circuit structure according to claim 12, wherein a conductive type of the well area and a conductive type of the deep well area are different.

14. The integrated circuit structure according to claim 12, wherein the deep well area is disposed in a substrate, and a conductive type of the substrate is different from a conductive type of the deep well area.

15. The integrated circuit structure according to claim 1, wherein the integrated circuit structure is disposed in a sense amplifying circuit of a memory device.
